(19) United States
(12) Patent Application Publication
(10) Pub. No.: US 2024/0417595 A1
(43) Pub. Date: Dec. 19, 2024

(54) POLISHING COMPOSITION AND POLISHING METHOD USING THE SAME

(71) Applicant: FUJIMI INCORPORATED, Kiyosu-shi (JP)

(72) Inventor: Tzu-Chun TSENG, Tongluo Township (TW)

(73) Assignee: FUJIMI INCORPORATED, Kiyosu-shi (JP)

(21) Appl. No.: 18/753,400

(22) Filed: Jun. 25, 2024

Related U.S. Application Data
(63) Continuation of application No. 16/976,603, filed on Aug. 28, 2020, now abandoned.

(30) Foreign Application Priority Data
Mar. 20, 2018 (JP) 2018-053106

(51) Int. Cl. C09G 1/02; C01B 33/12; H01L 21/321

(52) U.S. Cl. CPC C09G 1/02; C01B 33/12; H01L 21/3212

(57) ABSTRACT

Provided is a polishing composition that allows carbon-added silicon oxide (SiOC) to be polished at a higher polishing speed than the polishing speed of silicon nitride (i.e., the selection ratio of SiOC/silicon nitride is high).

A polishing composition containing spinous silica particles and a dispersing medium, in which the pH is less than 5.

### CROSS-REFERENCE TO RELATED APPLICATIONS

This application is a continuation of U.S. application Ser. No. 16/976,603, filed on Aug. 28, 2020, which is a 371 U.S. National Application of International Application No. PCT/JP2019/010307, filed on Mar. 13, 2019, which claims the benefit of and priority to Japanese Application No. 2018-053106, filed on Mar. 20, 2018, all of which are incorporated herein by reference in their entireties.

### TECHNICAL FIELD

The present invention relates to a polishing composition and a polishing method using the polishing composition.

### BACKGROUND ART

In recent years, a so-called chemical mechanical polishing (CMP) technique for physically polishing and flattening a semiconductor substrate in producing a device have been used in association with multilayer wiring on a surface of a semiconductor substrate. CMP is a method for flattening a surface of an object to be polished (polishing object) such as a semiconductor substrate by using a polishing composition (slurry) containing abrasive grains such as silica, alumina, or ceria, an anti-corrosion agent, a surfactant, or the like. CMP is specifically used in processes such as shallow trench isolation (STI), flattening of interlayer insulating films (ILD films), formation of tungsten plugs, and formation of multilayer interconnections composed of copper and a low dielectric film. In such a CMP, in the case of an STI process or the like, it has been desired that a first insulating film (e.g., carbon-added silicon oxide (SiOC) film) and a second insulating film (e.g., silicon nitride film) are polished and removed at a high polishing selection ratio (i.e., removing the SiOC film at a higher polishing speed than the polishing speed of the silicon nitride film).

As a technique described above, Japanese Patent Application Publication No. 2006-203188 discloses that the polishing speed of an insulating film (silicon nitride film, SiOC film or the like) is improved by using a chemical mechanical polishing composition containing methanesulfonic acid, an alkali metal ion, an oxidizing agent, and a silica polishing agent.

### SUMMARY OF INVENTION

However, when a polishing composition as described in Japanese Patent Application Publication No. 2006-203188 is used to polish an object to be polished containing silicon nitride and carbon-added silicon oxide (SiOC), SiOC and silicon nitride are both polished at a high speed, and therefore a high polishing selection ratio of SiOC to silicon nitride cannot be obtained.

The present invention is conceived in light of the above problems, and an object of the present invention is to provide a polishing composition in which the polishing speed of SiOC is sufficiently high relative to the polishing speed of silicon nitride (i.e., the selection ratio of SiOC/silicon nitride is high).

In light of the above problems, the inventors of the present invention conducted intensive studies. As a result, the inventors of the present invention found that the above-described problems can be solved by using a polishing composition which contains spinous silica particles and a dispersing medium, and in which the pH is less than 5, and completed the present invention accordingly.

### BRIEF DESCRIPTION OF DRAWINGS

FIG. 1 is a drawing illustrating spinous silica particles in an embodiment of the present invention.

### DESCRIPTION OF EMBODIMENTS

Hereinafter, the present invention will be described. Note that, the present invention is not limited to the following embodiments.

Incidentally, in the present specification, the term “(meth)acryl” in the specific name of a compound inclusively means “acryl” and “methacryl”, and “(meth)acrylate” inclusively means “acrylate” and “methacrylate”. Furthermore, “X to Y” indicating a range means “X or more and Y or less”, and “ppm”, “%”, and “parts”, respectively mean “mass parts per million”, “mass %”, and “parts by mass”. Further, unless otherwise noted, operations and measurement of physical properties or the like are performed under conditions at room temperature (20 to 25° C.) and a relative humidity of 40 to 50% RH.

The polishing composition according to the present invention is expected to be also effective for objects to be polished other than the object to be polished containing SiOC and silicon nitride. For example, the polishing composition according to the present invention is also expected to be effective for an object to be polished containing, for example, a silicon oxide film formed from TEOS as a raw material. Here, from the viewpoint of effects provided by the present invention, the polishing composition according to an embodiment of the present invention is preferably used in a process of polishing an object to be polished containing SiOC and silicon nitride. This is because, in such an object to be polished, the polishing selection ratio is presumably increased due to the mechanism described later.

The inventors of the present invention presume a mechanism to solve the above-described problems by the present invention as follows. Note that the following mechanism is only a presumption, and the scope of the present invention is not limited by this mechanism.

The polishing composition according to the present invention contains spinous silica particles and a dispersing medium, and the pH thereof is less than 5. In a case where the pH is less than 5, the surfaces of silicon nitride (isoelectric point is approximately less than 5) and silica particles are positively charged, and the surface of SiOC is negatively charged. Thus, it is conceived that SiOC and silica particles are adsorbed to each other, whereby the polishing speed of SiOC is increased, whereas silicon nitride and silica particles repulse against each other, whereby the polishing speed of silicon nitride is decreased, and, as a result, polishing in which the polishing speed of SiOC is sufficiently high relative to the polishing speed of silicon nitride could be achieved. Further, in the polishing composition according to the present invention, the surface morphology of silica particles has to be a spinous shape. Although the mechanism thereof is not clear, in a case where spinous silica particles are used, the polishing speed of SiOC is improved and the polishing speed of silicon nitride does not significantly change compared to a case where silica particles having a smooth surface are used. Thus, a high selection ratio of SiOC/silicon nitride can be achieved. That is, according to the present invention, a polishing composition in which the polishing speed of SiOC is sufficiently high relative to the polishing speed of silicon nitride (i.e., the selection ratio of SiOC/silicon nitride is high) is provided.

### Spinous Silica Particles

In the present specification, the term “spinous silica particle” refers to a silica particle having a plurality of protrusions on particle surface. Incidentally, the term “spinous silica particle” is also simply referred to as “silica particle” as below. In one or a plurality of embodiments, the spinous silica particles have a shape in which, based on the particles size of the smallest silica particle, two or more particles whose particle size are different five times or more are aggregated or fused. Among two or more particles whose particle sizes are different five times or more, a small particle is preferably partially embedded in a large particle. In a case where such spinous silica particles are used, the polishing speed of SiOC is improved and the polishing speed of silicon nitride does not significantly change compared to a case where silica particles having a smooth surface are used, and therefore a high selection ratio of SiOC/silicon nitride can be achieved.

Here, examples of the spinous silica particle include spinous colloidal silica, and spinous fumed silica. From the viewpoint of suppressing generation of polishing scratch, spinous colloidal silica is preferred.

### Method of Producing Spinous Silica Particles

Silica particles having a plurality of protrusions on the surface thereof, that is, spinous silica particles can be produced, for example, by the following method.

First, alkoxysilane is continuously added to a mixed solution of methanol and water in which ammonia aqueous solution has been added as a catalyst to perform hydrolysis, and thereby a slurry containing colloidal silica particles is obtained. The obtained slurry is heated to distill off methanol and ammonia. Then, an organic alkali as a catalyst is added to the slurry, and alkoxysilane is continuously added again thereto at a temperature of 70° C. or higher to perform hydrolysis, thus forming a plurality of protrusions on the surface of colloidal silica particles. Specific examples of the organic alkali that can be used herein include amine compounds such as triethanolamine, and quaternary ammonium compounds such as tetramethyl ammonium hydroxide. With this method, silica particles in which the content of metal impurities is 1 mass ppm or less and which has a plurality of protrusions on the surface thereof can be easily obtained. Further, in the later description, this production method may be referred to as “production method A”.

Note that a general method of producing colloidal silica through hydrolysis of alkoxysilane is described in, for example, “Science of Sol-Gel Method”, written by Sumio Sakuka (Agne Shofu Publishing Inc.), pp. 154 to 156. Japanese Patent Application Publication No. H11-60232 also discloses a method of producing cocoon-shaped colloidal silica, the method including adding dropwise methyl silicate or a mixture of methyl silicate and methanol to a mixed solvent containing water, methanol, and ammonia, or ammonia and an ammonium salt, thus reacting methyl silicate with water. Japanese Patent Application Publication No. 2001-48520 discloses a method of producing elongated colloidal silica, the method including hydrolyzing alkylsilicate with an acid catalyst, then adding an alkali catalyst thereto, and heating the mixture to proceed polymerization of silicic acid, thus growing particles. Japanese Patent Application Publication No. 2007-153732 describes a method of producing a colloidal silica having many small protrusions by using a specific amount of a specific type of hydrolysis catalyst and using readily hydrolyzable organosilicate as a raw material. Japanese Patent Application Publication No. 2002-338232 describes a method of producing secondary aggregated colloidal silica, the method including adding a flocculant to monodispersed colloidal silica, thus causing the colloidal silica particles to be secondarily aggregated into spherical shapes. Japanese Patent Application Publication No. H07-118008 and International Patent Application Publication No. 2007/018069 disclose that calcium salt or magnesium salt is added to active silicic acid obtained from sodium silicate to obtain heteromorphic colloidal silicas such as elongated colloidal silica. Japanese Patent Application Publication No. 2001-11433 describes that moniliform colloidal silica is obtained by adding calcium salt to active silicic acid obtained from sodium silicate. Japanese Patent Application Publication No. 2008-169102 descries that colloidal silica having many small protrusions like konpeito (Japanese confetti) is obtained by forming and growing microparticles on the surface of seed particles. The spinous silica particles according to the present invention can also be produced by using the method described in these literatures singly or in combination.

Note that the presence or absence of respective protrusions of spinous silica particles can be observed by a scanning electron microscope.

The number of protrusions of the surface of spinous silica particle is preferably 3 or more, and more preferably 5 or more, per particle on average.

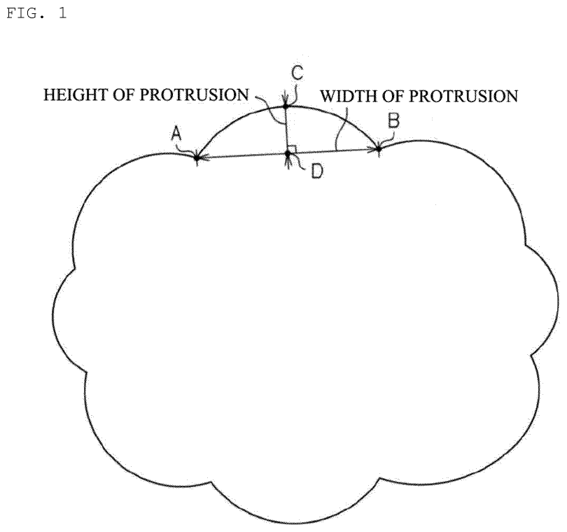

The protrusion herein is a protrusion having sufficiently small height and width compared to the particle size of the spinous silica particle. More specifically, a protrusion is such that the length of a portion shown in FIG. 1 as a curve AB which passes through a point A and a point B does not exceed one-fourth of the circumferential length of the maximum inscribed circle of the spinous silica particle, or more accurately, the circumferential length of the maximum circle inscribed in a projected contour of the outer shape of the spinous silica particle. Note that the width of the protrusion refers to the width of the base portion of the protrusion, and is represented as the distance between the point A and the point B in FIG. 1. The height of the protrusion refers to the distance between the base portion of the protrusion and a portion of the protrusion furthest from the base portion, and is expressed in FIG. 1 as the length of a segment CD which is orthogonal to a straight line AB.

The average of values obtained by dividing the height of the protrusions of the surface of spinous silica particles by the width of the base portion in corresponding protrusions (height of protrusion/width of protrusion) is preferably 0.170 or more, more preferably 0.200 or more, and even more preferably 0.220 or more. As the average of the values increases, the polishing speed with the polishing composition is improved because the shapes of the protrusions are comparatively sharp. Note that, the height of each protrusion and the width of base portion of each protrusion of the spinous silica particle can be determined by analyzing an image of the spinous silica particle observed by a scanning electron microscope using a common image analysis software.

The average height of protrusions of the surface of the spinous silica particle is preferably 3.5 nm or more, more preferably 4.0 nm or more, and even more preferably 5.0 nm or more. As the average height of protrusions increases, the polishing speed of SiOC by the polishing composition is improved.

The lower limit of the average primary particle size of the spinous silica particle is preferably 10 nm or more, more preferably 15 nm or more, and even more preferably 20 nm or more. Further, the upper limit of the average primary particle size of the spinous silica particle is preferably 200 nm or less, more preferably 150 nm or less, and even more preferably 100 nm or less. Within such a range, the polishing speed of an object to be polished (SiOC) by the polishing composition is improved, and defects generated on the surface of the object to be polished after polishing with the polishing composition can be suppressed. Note that the average primary particle size of the spinous silica particle is calculated based on, for example, the specific surface area of the spinous silica particle measured by the BET method.

The lower limit of the average secondary particle size of the spinous silica particle is preferably 15 nm or more, more preferably 20 nm or more, and even more preferably 30 nm or more. Further, the upper limit of the average secondary particle size of the spinous silica particle is preferably 300 nm or less, more preferably 260 nm or less, even more preferably 220 nm or less, particularly preferably 150 nm or less, and particularly preferably 100 nm or less. Within such a range, the polishing speed of an object to be polished (SiOC) by the polishing composition is improved, and defects generated on the surface of the object to be polished after polishing with the polishing composition can be suppressed. Incidentally, the secondary particle herein refers to a particle formed by the association of spinous silica particles in the polishing composition. The average secondary particle size of these secondary particles (average secondary particle size) can be measured by, for example, a dynamic light scattering method.

In the polishing composition according to the present invention, the content (concentration) of the spinous silica particles is not particularly limited. The content of the spinous silica particles is preferably 1 mass % or more, more preferably 2 mass % or more, and even more preferably 3 mass % or more relative to the amount of the polishing composition. The polishing speed of SiOC tends to be further increased with increase in the content of spinous silica particles. Further, from the viewpoint of preventing scratch or the like, usually, the content of the spinous silica particles is suitably 20 mass % or less, preferably 15 mass % or less, and more preferably 10 mass % or less. A small content of spinous silica particles is preferred from the viewpoint of economic efficiency.

### Cation-Modified Silica Particles

In the present invention, spinous silica particles may be modified with cation. The reason for this is as follows. In a case where the pH is less than 5, the surface of SiOC is negatively charged, and the surface of normal silica particles is positively charged, whereby SiOC and silica particles are adsorbed to each other. As a result, the polishing speed of SiOC is increased. On the contrary, silicon nitride is positively charged, whereby silicon nitride and silica particles repulse against each other. As a result, the polishing speed of silicon nitride is decreased. Here, in order to further enhance an adsorption force or a repulsive force between spinous silica particles and objects to be polished, the inventors of the present invention modified the surface of spinous silica particle with cation to introduce a positive (+) charge, and thus obtained cation-modified silica particles in which the positive absolute value of zeta potential is large under the condition that the pH is less than 5. That is, in the present invention, (spinous) cation-modified silica particles are preferably used. The cationic modification herein refers to a state in which a cation group (e.g., an amino group or a quaternary cation group) is bonded to the surface of silica particle. According to a preferred embodiment of the present invention, the cation-modified silica particle is an amino group-modified silica particle. According to such an embodiment, the effect of polishing with a high selection ratio of SiOC/silicon nitride can be enhanced.

Herein, the term “zeta (ζ) potential” refers to a difference in electric potential occurred in the interface between a solid and a liquid when the solid and the liquid in contact with each other relatively move. In a case where the pH is less than 5, silicon nitride and silica particles are similarly positively charged. Thus, when a difference in absolute value of zeta potential between silicon nitride and silica particles increases, the repulsion between silicon nitride and silica particles is strong, and the polishing speed is decreased. The difference in absolute value of zeta potential of silicon nitride and silica particles is not particularly limited, but is preferably 1 mV or more, more preferably 5 mV or more, and even more preferably 10 mV or more. On the contrary, SiOC is negatively charged. Thus, as a difference in the absolute value of zeta potential between SiOC and silica particles is increased, SiOC and silica particles become easy to contact, and the polishing speed is increased. The difference in absolute value of the zeta potential of SiOC and silica particles is not particularly limited, but is preferably 10 mV or more, more preferably 15 mV or more, and even more preferably 20 mV or more.

Here, spinous silica particles can be modified with cations by adding a silane coupling agent having a cation group to spinous silica particles, and allowing them to react at a predetermined temperature for a predetermined period of time.

The silane coupling agent used at that time is not particularly limited. Example thereof include N-(β-aminoethyl)-γ-aminopropylmethyldimethoxysilane, N-(β-aminoethyl)-γ-aminopropyltrimethoxysilane, N-(β-aminoethyl)-γ-aminopropyltriethoxysilane, γ-aminopropyltriethoxysilane ((3-aminopropyl) triethoxysilane), γ-aminopropyltrimethoxysilane,γ-triethoxysilyl-N-(α, γ-dimethyl-butylidene) propylamine, N-phenyl-γ-aminopropyltrimethoxysilane, N-(vinylbenzyl)-β-aminoethyl-γ-aminopropyltriethoxysilane hydrochloride, octadecyldimethyl-(γ-trimethoxysilylpropyl)-ammonium chlorid and the like. Among these, from the viewpoint of favorable reactivity with colloidal silica, N-(β-aminoethyl)-γ-aminopropyltrimethoxysilane, N-(β-aminoethyl)-γ-aminopropyltriethoxysilane, γ-aminopropyltriethoxysilane, or γ-aminopropyltrimethoxysilane is preferably used. Note that, in the present invention, one type of silane coupling agent may be used singly, or two or more types thereof may be used in combination.

Note that the silane coupling agent can be added to silica particles directly or by diluting with a hydrophilic organic solvent. By diluting the silane coupling agent with the hydrophilic organic solvent, production of aggregates can be suppressed. In a case where the silane coupling agent is diluted with a hydrophilic organic solvent, the silane coupling agent may be diluted with preferably 5 parts by mass or more and 50 parts by mass or less, or more preferably 10 parts by mass or more and 20 parts by mass or less of the hydrophilic organic solvent, per 1 part by mass of the silane coupling agent (in the case of containing two types or more, the total amount thereof). The hydrophilic organic solvent is not particularly limited, and examples thereof include lower alcohols such as methanol, ethanol, isopropanol, butanol, and the like.

Further, it is conceived that, by adjusting the pH of raw material silica and the amount of the silane coupling agent added, the amount of cation group introduced to the surface of silica particles can be adjusted. The amount of silane coupling agent used is not particularly limited, and the amount is preferably 0.01 mass % or more and 3.0 mass % or less, and more preferably approximately 0.05 mass % or more and 1.0 mass % or less relative to silica particles.

The treatment temperature for cationic modification of silica particles with a silane coupling agent is not particularly limited, and needs to be from room temperature (e.g., 25° C.) to around the boiling point of a dispersing medium to disperse silica particles. Specifically, the treatment temperature is 0° C. or higher and 100° C. or lower, and preferably around room temperature (e.g., 25° C.) or higher and 90° C. or lower.

### pH

The pH of the polishing composition according to the present invention is less than 5. As described above, it is conceived that, in a case where the pH is less than 5, the surfaces of silicon nitride and silica particles are positively charged, and the surface of SiOC is negatively charged, whereby SiOC and silica particles are adsorbed to each other, resulting in increase in the polishing speed of SiOC, whereas silicon nitride and silica particles repulse against each other, resulting in decrease in the polishing speed of silicon nitride, and as a result, polishing, in which the polishing speed of SiOC is sufficiently high relative to the polishing speed of silicon nitride, could be achieved. In a preferred embodiment, the pH of the polishing composition is 4.5 or less, more preferably 4 or less, and even more preferably 3.8 or less.

The lower limit of the pH of the polishing composition is not particularly limited, but is preferably 1 or more, more preferably 1.5 or more, even more preferably 2 or more, particularly preferably 2.5 or more, and most preferably 3 or more, from the perspectives of facilitating handling, and improving the polishing speed of SiOC and the selection ratio of SiOC/SiN.

For example, in a preferred embodiment, the pH of the polishing composition is 2 or more and 4 or less.

A pH adjusting agent is used for adjusting the pH of the polishing composition of the present invention.

As the pH adjusting agent, a publicly known acid, a base, or salts thereof can be used.

Specific examples of the acid that can be used as the pH adjusting agent include, for example, inorganic acids such as hydrochloric acid, sulfuric acid, nitric acid, hydrofluoric acid, boric acid, carbonic acid, hypophosphorous acid, phosphorous acid, and phosphoric acid; and organic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, gluconic acid, itaconic acid, tartaric acid, citric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenyl acetic acid, phenoxyacetic acid, and the like. In a case where an inorganic acid is used as the pH adjusting agent, in particular, sulfuric acid, nitric acid or phosphoric acid is particularly preferred from the viewpoint of improving the polishing speed. In a case where an organic acid is used as the pH adjusting agent, glycolic acid, succinic acid, maleic acid, citric acid, tartaric acid, malic acid, gluconic acid, and itaconic acid are preferred.

Specific examples of the base that can used as the pH adjusting agent include, for example, amines such as aliphatic amines, and aromatic amine; organic bases such as quaternary ammonium hydroxide; hydroxides of alkali metals such as potassium hydroxide; hydroxides of alkaline earth metals; tetramethyl ammonium hydroxide; ammonia; and the like. Among these, potassium hydroxide or ammonia is preferred from the viewpoint of procurement ease.

The pH adjusting agent can be used singly or two or more types thereof may be mixed and used.

The amount of the pH adjusting agent added is not particularly limited, and the amount may be appropriately selected so that the pH is within a target pH range in the present invention.

### Dispersing Medium

In the polishing composition of the present invention, a dispersing medium is used for dispersing respective components constituting the polishing composition. Examples of the dispersing medium include organic solvents, and water, and among them, the dispersing medium preferably contains water.

From the viewpoint of suppressing contamination on an object to be polished and inhibition to actions of other components, water that does not contain impurities as much as possible is preferred. Specifically, deionized water, pure water, or the like is preferred. Such water can be obtained by, for example, removing impurity ions with ion exchange resins and then removing foreign substances through a filter, for example.

### Polishing Method

In the present invention, a polishing method including a step of polishing a surface of an object to be polished by using the above-described polishing composition is also provided. The object to be polished preferably contains SiOC and silicon nitride. With such a polishing method, SiOC can be selectively polished relative to silicon nitride.

A polishing apparatus is not particularly limited, and, for example, it is possible to use a general polishing apparatus including a holder for holding a substrate or the like having an object to be polished, a motor or the like having a changeable rotation number, and a polishing table to which a polishing pad (polishing cloth) can be attached.

As the polishing pad, a general non-woven fabric, polyurethane, a porous fluororesin, or the like can be used without any particular limitation.

The polishing conditions are also not particularly limited. For example, the rotation speed of a polishing table is preferably 10 rpm or more and 200 rpm or less, the carrier (head) rotation speed is preferably 10 rpm or more and 200 rpm or less, and the pressure (polishing pressure) applied to a substrate having an object to be polished is preferably 0.5 psi or more and 10 psi or less. A method for supplying a polishing composition to a polishing pad is not particularly limited. For example, a method in which a polishing composition is continuously supplied using a pump or the like can be employed (discarded after single use). The supply amount is not limited, but a surface of the polishing pad is preferably covered all the time with the polishing composition of the present invention.

### Method of Producing Semiconductor Substrate

In the present invention, a method of producing a semiconductor substrate, including a step of polishing an object to be polished by the above-described polishing method is also provided. Since the method of producing a semiconductor substrate of the present invention includes the above-described polishing method, SiOC can be selectively polished relative to silicon nitride, and a semiconductor substrate can be produced according to the purpose.

### EXAMPLES

The present invention will be described in greater detail with the following Examples and Comparative Examples. However, the technical scope of the present invention is not limited only to the following Examples.

### Preparation of Polishing Composition

### Example 1

A colloidal silica dispersion containing 20 mass % of colloidal silica (spinous shape; colloidal silica produced by the above-described production method A; primary particle size: 48.4 nm; secondary particle size: 63.1 nm; average height of protrusion: 5.66 nm; and protrusion height/protrusion width=0.25) was prepared using pure water as a dispersing medium. Then, a polishing composition was prepared, using nitric acid and pure water, so that the content of colloidal silica in the polishing composition was finally 3.2 mass % and the pH was 2.7.

### Example 2

A polishing composition was prepared in the same manner as in Example 1 except that the pH was adjusted to 3.4.

### Example 3

A colloidal silica dispersion containing 20 mass % of colloidal silica (spinous shape; and colloidal silica similar to one of Example 1) was prepared using pure water as a dispersing medium. To 1 kg of the colloidal silica dispersion, 0.11 g of (3-aminopropyl) triethoxysilane (APTES) was gradually added (one drop every approximately 5 seconds, and approximately 0.03 g per drop). During addition, the colloidal silica dispersion was stirred with a stirrer at a rate of 300 to 400 rpm. After completion of addition of APTES, stirring was continued at room temperature (25° C.) for 5 hours. After completion of stirring, a mixture of colloidal silica and ATPES was diluted with water, and the pH value of the resulting mixture was adjusted to 2.6 with nitric acid. Then, a polishing composition was prepared so that the content of colloidal silica in the polishing composition was finally 3.2 mass % and the content of APTES was 17.6 ppm.

### Examples 4 to 8

Polishing compositions of Examples 4 to 8 were prepared in the same manner as in Example 3 except that the pH was adjusted to each of the values described in Table 1.

### Comparative Example 1

The polishing composition of Comparative Example 1 was prepared in the same manner as in Example 1 except that the pH was adjusted to 5.0.

### Comparative Examples 2 to 7

Polishing compositions of Comparative Examples 2 to 7 were prepared in the same manner as in Example 3 except that the pH was adjusted to each of the values described in Table 1.

### Comparative Examples 8 to 12

Polishing compositions of Comparative Examples 8 to 12 were prepared in the same manner as in Example 1 except that colloidal silica with a smooth surface (primary particle size: 32 nm; and secondary particle size: 61 nm) was used as silica particles, and further, the pH was adjusted to each of the values described in Table 1.

### Comparative Examples 13 to 18

Polishing compositions of Comparative Examples 13 to 18 were prepared in the same manner as in Example 3 except that colloidal silica with a smooth surface (primary particle size: 32 nm; and secondary particle size: 61 nm) was used as silica particles, and further, the pH was adjusted to each of the values described in Table 1.

### CMP Step

An SiOC wafer and a silicon nitride wafer were polished using respective polishing compositions under the following conditions. Here, a wafer with a size of 300 mm was used for the SiOC wafer and the silicon nitride wafer. Then, for collecting data for the polishing speed, the SiOC wafer and the silicon nitride wafer were cut into a square of 3 cm×3 cm.

### Polishing Conditions

Polishing apparatus: EJ-380IN-CH manufactured by Engis Japan Corporation
Polishing pad: IC1010 manufactured by The Dow Chemical Company
Polishing pressure: 1.4 psi (1 psi=6894.76 Pa, the same applies hereinafter)
Number of rotations of polishing pad: 100 rpm
Supply of polishing composition: Discard after single use
Amount of polishing composition supplied: 100 mL/min
Polishing time: 60 seconds

Specifically, polishing was performed by the following procedures:
1. A polishing pad was subjected to flushing with deionized water (DIW).
2. The DIW was continuously flushed, and the conditioning of the polishing pad was started at a rotation speed of 100 rpm for 20 seconds by diamond conditioning.
3. A polishing composition was dropped onto the center of the polishing pad for 30 seconds (during which the polishing pad is rotated), and the polishing composition was allowed to be uniformly dispersed on the polishing pad.
4. An SiOC wafer or a silicon nitride wafer was placed on a wafer carrier, and the carrier was set on the polishing pad.
5. The start button of the polishing apparatus was turned on, the polishing pad was then accelerated to a rotation speed of 100 rpm, and polishing was performed.
6. The wafer was removed from the polishing apparatus, and then washed with DIW and dried in dry air.

### Evaluation of Polishing Selection Ratio

Firstly, the polishing speed was determined for respective objects to be polished after the polishing by using the following Equation 1. The evaluation results are shown in Table 1.

$$\begin{matrix}[ Equation 1 ] & \\ & Equation 1\end{matrix}$$

$$Polishing speed ( A / min ) = \frac{\begin{matrix}Thickness of substrate before polishing ( A ) - \\ Thickness of substrate after polishing ( A )\end{matrix}}{Polishing time ( min )}$$

Further, in Examples, evaluation was performed by using each of the SiOC wafer and silicon nitride wafer. However, it is presumed that, in a case where a wafer (substrate) containing both SiOC and silicon nitride, or the like is used, a result equivalent to the above can also be obtained.

Then, the polishing selection ratio of the SiOC wafer and the silicon nitride wafer was determined. From the viewpoint of solving the problems of the present invention, the polishing selection ratio (SiOC/SiN) is preferably 15 or more.

TABLE 1

| | Surface | | | | Polishing | | |
|---|---|---|---|---|---|---|---|
| | morphology | | pH | | ratio | | Selection |
| | of silica | Coupling | adjusting | | [Å/min.] | | ratio |
| | particle | agent | agent | pH | SiOC | SiN | SiOC/SiN |
| Example 1 | Spinous shape | — | Nitric acid | 2.7 | 1204 | 56 | 21.6 |
| Example 2 | Spinous shape | — | Nitric acid | 3.4 | 1586 | 67 | 23.5 |
| Example 3 | Spinous shape | APTES | Nitric acid | 2.6 | 781 | 37 | 21.2 |
| Example 4 | Spinous shape | APTES | Nitric acid | 2.9 | 1191 | 39 | 30.4 |
| Example 5 | Spinous shape | APTES | Nitric acid | 3.2 | 1602 | 39 | 40.9 |
| Example 6 | Spinous shape | APTES | Nitric acid | 3.4 | 1905 | 39 | 48.4 |
| Example 7 | Spinous shape | APTES | Nitric acid | 3.6 | 2135 | 45 | 47.9 |
| Example 8 | Spinous shape | APTES | Nitric acid | 3.9 | 1837 | 92 | 19.9 |
| Comparative | Spinous shape | — | Nitric acid | 5.0 | 305 | 370 | 0.8 |
| Example 1 | | | | | | | |
| Comparative | Spinous shape | APTES | Nitric acid | 5.2 | 282 | 276 | 1.0 |
| Example 2 | | | | | | | |
| Comparative | Spinous shape | APTES | Nitric acid | 6.3 | 205 | 160 | 1.3 |
| Example 3 | | | | | | | |
| Comparative | Spinous shape | APTES | Nitric acid | 7.2 | 133 | 36 | 3.7 |
| Example 4 | | | | | | | |
| Comparative | Spinous shape | APTES | NH₄OH | 9.2 | 18 | 2 | 11.5 |
| Example 5 | | | | | | | |
| Comparative | Spinous shape | APTES | NH₄OH | 10.1 | 62 | 11 | 5.5 |
| Example 6 | | | | | | | |
| Comparative | Spinous shape | APTES | NH₄OH | 11.0 | 74 | 16 | 4.6 |
| Example 7 | | | | | | | |
| Comparative | Smooth | — | Nitric acid | 1.5 | 209 | 150 | 1.4 |
| Example 8 | | | | | | | |
| Comparative | Smooth | — | Nitric acid | 2.7 | 329 | 45 | 7.3 |
| Example 9 | | | | | | | |
| Comparative | Smooth | — | Nitric acid | 3.5 | 401 | 75 | 5.3 |
| Example 10 | | | | | | | |
| Comparative | Smooth | — | Nitric acid | 4.1 | 332 | 292 | 1.1 |
| Example 11 | | | | | | | |
| Comparative | Smooth | — | Nitric acid | 6.1 | 75 | 195 | 0.4 |
| Example 12 | | | | | | | |
| Comparative | Smooth | APTES | Acetic acid | 2.4 | 245 | 30 | 8.2 |
| Example 13 | | | | | | | |
| Comparative | Smooth | APTES | Acetic acid | 3.4 | 179 | 20 | 9.0 |
| Example 14 | | | | | | | |
| Comparative | Smooth | APTES | Acetic acid | 4.4 | 531 | 80 | 6.6 |
| Example 15 | | | | | | | |
| Comparative | Smooth | APTES | Acetic acid | 5.4 | 182 | 107 | 1.7 |
| Example 16 | | | | | | | |
| Comparative | Smooth | APTES | Acetic acid | 6.4 | 51 | 56 | 0.9 |
| Example 17 | | | | | | | |
| Comparative | Smooth | APTES | Acetic acid | 7.4 | 37 | 20 | 1.9 |
| Example 18 | | | | | | | |

From the results of Table 1, it was found that, in Examples 1 to 8 in which the polishing compositions of the present invention were used, the polishing speed of SiOC relative to the polishing speed of silicon nitride (SiOC/SiN selection ratio) was sufficiently high. Among these Examples, from the comparison of Examples 2 and 6, it was found that, in a case where spinous silica particles modified with cation were used, a more excellent selection ratio was obtained. Meanwhile, in Comparative Examples 1 to 7 in which the pH was 5 or more, spinous silica particles were used, but the SiOC/SiN selection ratio was low. Further, in Comparative Examples 8 to 18, since spinous silica particles were not used, the SiOC/SiN selection ratio was low regardless of the value of the pH.

1.-8. (canceled)

9. A polishing composition, comprising:
spinous silica particles; and
a dispersion medium,
wherein the polishing composition has a pH of 2.6 or more and less than 5 and a polishing selectivity ratio of carbon-added silicon oxide to silicon nitride (SiOC/SiN) of 15 or more.

10. The polishing composition of claim 9, wherein the polishing selectivity ratio of carbon-added silicon oxide to silicon nitride (SiOC/SiN) is 19.9 to 48.4.

11. The polishing composition of claim 9, wherein the polishing selectivity ratio of carbon-added silicon oxide to silicon nitride (SiOC/SiN) is 30.4 to 48.4.

12. The polishing composition of claim 9, wherein the spinous silica particles have an average particle diameter of 10 nm or more and 100 nm or less.

13. The polishing composition of claim 9, wherein the spinous silica particles have a positive zeta potential at pH less than 5.

14. The polishing composition of claim 9, wherein the spinous silica particles are cation-modified.

15. The polishing composition of claim 9, wherein the spinous silica particles are modified with N-(β-aminoethyl)-γ-aminopropyltrimethoxysilane, N-(β-aminoethyl)-γ-aminopropyltriethoxysilane, γ-aminopropyltriethoxysilane (APTES), γ-aminopropyltrimethoxysilane, or a combination thereof.

16. The polishing composition of claim 9, wherein the spinous silica particles are modified with γ-aminopropyltriethoxysilane (APTES).

17. The polishing composition of claim 9, wherein the spinous silica particles are modified with a silane coupling agent, wherein the silane coupling agent is present at 0.01 mass % or more and 3.0 mass % or less, relative to the mass of the spinous silica particles.

18. The polishing composition of claim 17, wherein the silane coupling agent is present at 0.05 mass % or more and 1.0 mass % or less, relative to the mass of the spinous silica particles.

19. The polishing composition of claim 9, wherein the spinous silica particles are present at a concentration of 1 mass % or more and 10 mass % or less.

20. The polishing composition of claim 9, wherein the polishing composition comprises a pH adjuster, wherein the pH adjuster is an acid.

21. The polishing composition of claim 20, wherein the pH adjuster is selected from sulfuric acid, nitric acid, phosphoric acid, or a combination thereof.

22. The polishing composition of claim 20, wherein the pH adjuster is nitric acid.

23. The polishing composition of claim 20, wherein the pH adjuster is selected from glycolic acid, succinic acid, maleic acid, citric acid, tartaric acid, malic acid, gluconic acid, itaconic acid, or a combination thereof.

24. The polishing composition of claim 9, wherein a concentration of metal impurities in the spinous silica particles is 1 ppm by mass or less.

25. The polishing composition of claim 9, wherein the spinous silica particles are cation modified by a process comprising:
diluting a silane coupling agent with a hydrophilic organic solvent at 5 parts by mass or more and 50 parts by mass or less per 1 part by mass of the silane coupling agent; and
adding diluted silane coupling agent to the spinous silica particles.

26. The polishing composition of claim 25, wherein the hydrophilic organic solvent comprises methanol, ethanol, isopropanol, butanol, or a combination thereof.
